(19) United States
(12) Patent Application Publication
(10) Pub. No.: US 2022/0131341 A1
(43) Pub. Date: Apr. 28, 2022

(54) SEMICONDUCTOR LASER DIODE AND METHOD FOR PRODUCING A SEMICONDUCTOR LASER DIODE

(71) Applicant: OSRAM Opto Semiconductors GmbH, Regensburg (DE)

(72) Inventors: Sven GERHARD, Alteglofsheim (DE); Christoph EICHLER, Donaustauf (DE); Alfred LELL, Maxhütte-Haidhof (DE); Muhammad ALI, Cambourne (GB)

(21) Appl. No.: 17/437,150

(22) PCT Filed: Feb. 13, 2020
(86) PCT No.: PCT/EP2020/053776

§ 371 Date: Sep. 8, 2021

(30) Foreign Application Priority Data
Mar. 14, 2019 (DE) 10 2019 106 536.4

(51) Int. Cl. H01S 5/042; H01S 5/22; H01S 5/343; H01S 5/026; H01L 33/62

(52) U.S. Cl. CPC H01S 5/04253; H01S 5/22; H01L 33/62; H01S 5/026; H01S 5/0421; H01S 5/34333

(57) ABSTRACT

The invention relates to a semiconductor laser diode, which comprises a semiconductor layer sequence grown in a vertical direction and having an active layer that is configured and provided to generate light during operation in at least one active region extending in a longitudinal direction, and which comprises a transparent electrically conductive cover layer on the semiconductor layer sequence, wherein the semiconductor layer sequence terminates in a vertical direction with a top side, and the top side has a contact region arranged in the vertical direction above the active region and at least one cover region directly adjoining the contact region in a lateral direction perpendicular to the vertical and longitudinal directions, the cover layer is applied contiguously to the contact region and the at least one cover region on the top side, the cover layer is applied directly to the top side of the semiconductor layer sequence at least in the at least one cover region, and at least one element defining the at least one active region is present which is covered by the cover layer. The invention further relates to a method of manufacturing a semiconductor laser diode.

### CROSS-REFERENCE TO RELATED APPLICATIONS

This patent application is a national stage entry from International Application No. PCT/EP2020/053776, filed on Feb. 13, 2020, published as International Publication No. WO 2020/182406 A1 on Sep. 17, 2020, and claims priority under 35 U.S.C. § 119 from German patent application 10 2019 106 536.4, filed Mar. 14, 2019, the disclosure content of all of which are hereby incorporated by reference.

### FIELD OF THE INVENTION

A semiconductor laser diode and a method of manufacturing a semiconductor laser diode are specified.

### BACKGROUND OF THE INVENTION

Commonly used laser diodes have, on the side facing away from the substrate, a dielectric passivation, which can also cover the side surfaces of a ridge waveguide structure depending on the laser diode design. After the ridge waveguide structure has been manufactured and overmolded with a passivation material, it must be removed again in the area where electrical contact is to be made. The steps required in this context can be very elaborate, especially if the structural sizes of the ridge waveguide structure are in the range of a few micrometers. In addition, the usual dielectric passivation materials, such as SiO₂ or Si₃N₄, have only a low thermal conductivity, which can have a disadvantageous effect, especially when mounting such a laser diode with the passivated side on a carrier.

It is at least one aim of certain embodiments to specify a semiconductor laser diode. It is at least another aim of certain embodiments is to specify a method of manufacturing a semiconductor laser diode.

These aims are achieved by an object and a method according to the independent patent claims. Advantageous embodiments and further developments of the object and the method are characterized in the dependent claims and furthermore will become apparent from the following description and the drawings.

### SUMMARY OF THE INVENTION

According to at least one embodiment, a semiconductor laser diode comprises at least one active layer that is configured and provided to generate light in an active region during operation. The active layer can in particular be part of a semiconductor layer sequence comprising a plurality of semiconductor layers, and have a main extension plane that is perpendicular to an arrangement direction of the layers of the semiconductor layer sequence. For example, the active layer may have exactly one active region. Further, the active layer may also have a plurality of active regions. An active region may be effected by one or more elements defining an active region described further below. The term “at least one active region” as used below may refer to embodiments having exactly one active region, as well as embodiments having multiple active regions.

According to a further embodiment, in a method of manufacturing a semiconductor laser diode, a semiconductor layer sequence is provided which comprises an active layer that is configured and provided to generate light during operation of the semiconductor laser diode. In particular, the semiconductor layer sequence having the active layer may be produced by means of an epitaxial method. The embodiments and features described above and below apply equally to the semiconductor laser diode and to the method of manufacturing the semiconductor laser diode.

According to a further embodiment, the semiconductor laser diode has a light outcoupling surface and a rear surface opposite the light outcoupling surface. The light outcoupling surface and the rear surface can in particular be side surfaces of the semiconductor laser diode, particularly preferably side surfaces of the semiconductor layer sequence, which can also be referred to as so-called facets. During operation, the semiconductor laser diode can radiate the light generated in the at least one active region via the light outcoupling surface. Suitable optical coatings, in particular reflective or partially reflective layers or layer sequences, can be applied to the light outcoupling surface and the rear surface and can form an optical resonator for the light generated in the active layer. The at least one active region may extend between the rear surface and the light outcoupling surface along a direction that is referred to here and in the following as the longitudinal direction. In particular, the longitudinal direction may be parallel to the main extension plane of the active layer. The direction of arrangement of the layers on top of each other, i.e. a direction perpendicular to the main extension plane of the active layer, is referred to here and in the following as the vertical direction. A direction perpendicular to the longitudinal direction and perpendicular to the vertical direction is referred to here and in the following as the lateral direction. The longitudinal direction and the lateral direction can thus span a plane that is parallel to the main extension plane of the active layer.

The semiconductor layer sequence can be designed in particular as an epitaxial layer sequence, i.e. as an epitaxially grown semiconductor layer sequence. For example, the semiconductor layer sequence can be based on InAlGaN. InAlGaN-based semiconductor layer sequences include, in particular, those in which the epitaxially grown semiconductor layer sequence generally has a layer sequence of different individual layers, which contains at least one individual layer that comprises a material from the III-V compound semiconductor material system InₓAl_{y}Ga_{1-x-y}N with 0≤x≤1, 0≤y≤1 and x+y≤1. In particular, the active layer may be based on such a material. Semiconductor layer sequences comprising at least one active layer based on InAlGaN can, for example, preferentially emit electromagnetic radiation in an ultraviolet to green wavelength range.

Alternatively or additionally, the semiconductor layer sequence can also be based on InAlGaP, i.e., the semiconductor layer sequence can have different individual layers, of which at least one individual layer, for example the active layer, comprises a material from the III-V compound semiconductor material system InₓAl_{y}Ga_{1-x-y}P with 0≤x≤1, 0≤y≤1 and x+y≤1. Semiconductor layer sequences comprising at least one active layer based on InAlGaP can, for example, preferentially emit electromagnetic radiation with one or more spectral components in a green to red wavelength range.

Alternatively or additionally, the semiconductor layer sequence may include other III-V compound semiconductor material systems, such as an InAlGaAs-based material, or II-VI compound semiconductor material systems. In particular, an active layer comprising an InAlGaAs-based material may be capable of emitting electromagnetic radiation having one or more spectral components in a red to infrared wavelength range. A II-VI compound semiconductor material may include at least one element from the second main group, such as Be, Mg, Ca, Sr, and one element from the sixth main group, such as O, S, Se. For example, II-VI compound semiconductor materials include ZnSe, ZnTe, ZnO, ZnMgO, CdS, ZnCdS, and MgBeO.

The active layer and in particular the semiconductor layer sequence comprising the active layer can be deposited on a substrate. For example, the substrate can be designed as a growth substrate on which the semiconductor layer sequence is grown. The active layer and in particular the semiconductor layer sequence comprising the active layer can be produced by means of an epitaxial method, for example by means of metal organic vapor phase epitaxy (MOVPE) or molecular beam epitaxy (MBE). In particular, this may mean that the semiconductor layer sequence is grown on the growth substrate. Furthermore, the semiconductor layer sequence can be provided with electrical contacts in the form of one or more contact elements. Moreover, it may also be possible that the growth substrate is removed after the growth process. In this case, the semiconductor layer sequence can, for example, also be transferred to a substrate formed as a carrier substrate after the growth process. The substrate may comprise a semiconductor material, for example a compound semiconductor material system mentioned above, or another material. In particular, the substrate may comprise or be made of sapphire, GaAs, GaP, GaN, InP, SiC, Si, Ge, and/or a ceramic material such as SiN or AlN.

For example, the active layer may have a conventional pn junction, a double heterostructure, a single quantum well (SQW) structure, or a multiple quantum well (MQW) structure for light generation. In addition to the active layer, the semiconductor layer sequence may include additional functional layers and functional regions, such as p-doped or n-doped charge carrier transport layers, i.e., electron or hole transport layers, undoped or p-doped or n-doped confinement, cladding or waveguide layers, barrier layers, planarization layers, buffer layers, protective layers and/or electrode layers, and combinations thereof. Furthermore, additional layers, such as buffer layers, barrier layers and/or protective layers can also be arranged perpendicular to the growth direction of the semiconductor layer sequence, for example around the semiconductor layer sequence, i.e. for example on the side surfaces of the semiconductor layer sequence.

According to a further embodiment, the semiconductor laser diode comprises a transparent electrically conductive cover layer on the semiconductor layer sequence. In particular, the semiconductor layer sequence may terminate with a top side along the vertical direction. In particular, the cover layer may be applied to the top side. The top side can particularly preferably be formed by the side of the semiconductor layer sequence facing away from a substrate. Here, the substrate can be a growth substrate or a carrier substrate. If the semiconductor laser diode does not have a substrate after a detachment of the growth substrate, the top side can particularly preferably be formed by the side opposite the detached growth substrate. Preferably, the cover layer may be at least partially directly adjacent to the semiconductor material of the top side of the semiconductor layer sequence and thus in direct contact with the semiconductor material of the top side of the semiconductor layer sequence. For example, the cover layer may be in direct contact with the top side in the entire area of the top side covered by the cover layer. Furthermore, it may also be possible that the cover layer is not in direct contact with the top side of the semiconductor layer sequence in the vertical direction above the at least one active region, while the cover layer is applied in direct contact with the top side of the semiconductor layer sequence in at least one region laterally offset thereto.

According to a further embodiment, the cover layer comprises at least one transparent electrically conductive oxide (TCO). Transparent electrically conductive oxides are transparent electrically conductive materials, usually metal oxides, such as zinc oxide, tin oxide, cadmium oxide, titanium oxide, indium oxide or indium tin oxide (ITO). In addition to binary metal oxygen compounds such as, for example, ZnO, SnO₂ or In₂O₃, ternary metal oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Particularly preferably, the cover layer may comprise one or more of the following materials: ITO, also denominable as In₂O₃:Sn, particularly preferably with a proportion greater than or equal to 90% and less than or equal to 95% In₂O₃ and greater than or equal to 5% and less than or equal to 10% SnO₂; In₂O₃; SnO₂; Sn₂O₃; ZnO; IZO (indium zinc oxide); GZO (gallium-doped zinc oxide). Furthermore, it may be possible that the TCO or TCOs of the cover layer do not necessarily correspond to a stoichiometric composition and may also be p-doped or n-doped.

The cover layer is particularly suitable for current injection into the semiconductor layer sequence from the top side. The cover layer can thus form a transparent electrical contact layer. A contact element in the form of an electrode layer can be present on the bottom surface of the semiconductor layer sequence opposite the cover layer. For external electrical connection of the cover layer, for example by means of a solder or bonding wire connection, a metallic contact element can be arranged on the side of the cover layer facing away from the semiconductor layer sequence. The contact element can be a bonding layer for wire bonding or for soldering on the semiconductor laser diode and, for example, be of single-layer or multilayer design and contain aluminum and/or silver and/or gold or be made of these. In particular, the contact element or even a plurality of contact elements may be arranged on the cover layer only in one or more areas required for electrical connection by soldering or wire bonding. In particular, the one or more contact elements may be arranged independently of the requirements with respect to current injection into the semiconductor layer sequence. Preferably, the one or more contact elements may be arranged directly on the cover layer.

According to a further embodiment, the top side comprises a contact region arranged vertically above the at least one active region. Laterally offset from the contact region, the top side has a cover region directly adjacent to the contact region. This can also mean that the contact region is arranged in the lateral direction between two cover regions, each of which is directly adjacent to the contact region in the lateral direction. In particular, the contact region may have a main extension direction along the longitudinal direction and thus preferably be designed in the form of a strip which preferably extends from the radiation outcoupling surface to the rear surface and which is arranged along the lateral direction between two cover regions. The features and embodiments described below mainly in connection with “at least one cover region” refer to embodiments with exactly one cover region as well as to embodiments with two or more cover regions directly adjacent to the contact region.

During operation of the semiconductor laser diode, current can be injected into the semiconductor layer sequence from the top side of the semiconductor layer sequence via the contact region. In particular, more current is injected into the top side of the semiconductor layer sequence via the contact region than via the at least one cover region during operation. This may mean in particular that current injection via the contact region occurs at least preferentially or at least substantially or even exclusively, while during operation of the semiconductor laser diode less current injection occurs via the cover region than via the contact region or substantially no current injection occurs or even no current injection occurs at all.

According to a further embodiment, the cover layer is applied contiguously to the contact region and the at least one cover region on the top side. The cover layer particularly preferably covers the entire contact region and at least part of, or also the entire at least one cover region.

According to a further embodiment, the cover layer covers the entire top side of the semiconductor layer sequence. Alternatively, the cover layer may cover only part of the top side of the semiconductor layer sequence. The part of the top side not covered by the cover layer in this case can be selected such that it has no influence on the formation of the active region and thus on the optical properties of the semiconductor laser diode, whether the cover layer is present in this part or not. In particular, the cover layer can extend laterally over the top side of the semiconductor layer sequence to such an extent that the region or regions not covered by the cover layer have no influence on the mode structure and thus on the active region.

According to a further embodiment, the semiconductor laser diode comprises at least one element defining the at least one active region and being covered by the cover layer. The at least one element defining the at least one active region may also be referred to in short as the defining element in the following. Particularly preferably, the at least one defining element may be arranged on the top side of the semiconductor layer sequence, for example in the form of a topographic structure of the top side and/or in the form of a semiconductor structure of the top side and/or in the form of a layer applied to the top side of the semiconductor layer sequence. The fact that a defining element defines the at least one active region may mean that the formation of optical modes in the active layer and thus the formation of an active region during laser operation depends on the specific design of the defining element. In other words, by modifying the defining element, the forming active region can be modified. The defining element thus serves to set a concretely targeted mode distribution and thus a concretely targeted active region. In particular, the at least one defining element can influence at least one optical property of at least part of the semiconductor layer sequence and/or at least one property relating to the current injection. One or more defining elements may be provided for defining an active region. In particular, an interaction of several defining elements may lead to a desired formation of the active region.

According to a further embodiment, in the method of manufacturing the semiconductor laser diode, the semiconductor layer sequence having the active layer and having the top side with the contact region and the at least one cover region is provided. Meanwhile and/or subsequently, the at least one element defining the active region may be formed and the cover layer may be applied contiguously to the contact region and the at least one cover region.

According to a further embodiment, the at least one defining element comprises or is formed by a ridge formed in the contact region of the top side. For example, the ridge can be formed by a part of the semiconductor layer sequence. In particular, the ridge may be formed by a ridge-shaped raised region extending in the longitudinal direction on the top side of the semiconductor layer sequence. In other words, the ridge projects in the vertical direction beyond the laterally adjacent surface regions and extends in the longitudinal direction. In particular, the side surfaces bounding the ridge in the lateral direction may form a step profile with the adjacent surface regions of the top side of the semiconductor layer sequence. The terms “ridge-shaped region” and “ridge” may be used interchangeably in the following. Furthermore, the semiconductor layer sequence may also have a plurality of ridge-shaped regions arranged laterally adjacent to and spaced apart from each other, each extending in the longitudinal direction. To form the ridge, a portion of the semiconductor layer sequence may be removed from the top side after the semiconductor layer sequence has been grown. In particular, the removal may be performed by an etching process. The cover layer can particularly preferably cover the entire ridge and in particular extend in the lateral direction from the ridge over the top side of the semiconductor layer sequence.

Particularly preferably, the contact region can be formed by a top side of the ridge. In other words, the contact region has the same shape as the ridge when viewed from above the top side of the semiconductor layer sequence in the vertical direction. Thus, the shape of the ridge and, in particular, the shape of the top side of the ridge can determine the shape of the contact region and, thus, the region for current injection. Furthermore, the contact region can additionally include the ridge side surfaces laterally bounding the ridge or a part thereof.

Furthermore, the ridge can form a ridge waveguide structure for index guidance of the light generated in the active region. In this case, the ridge has a sufficient height and a sufficient proximity to the active layer so that the waveguiding and thus the mode formation in the active layer are influenced by the ridge. Alternatively, the ridge may have such a small height and such a large distance from the active layer that little or even no index guidance of the light generated in the active region is caused by the ridge. In other words, in this case the ridge can be designed in such a way that the mode formation in the active layer is predominantly or even exclusively caused by gain guiding.

Furthermore, the semiconductor layer sequence can have a first semiconductor material in the contact region and a second semiconductor material in the cover region due to the formation of the ridge, wherein the first semiconductor material can have a higher electrical conductivity and/or a lower electrical contact resistance to the cover layer than the second semiconductor material. For example, the semiconductor layer sequence can terminate in the vertical direction towards the top with a cladding layer and, above it, a semiconductor contact layer, wherein the semiconductor contact layer can have a higher doping and thus a higher electrical conductivity and/or a lower electrical contact resistance to the cover layer than the cladding layer. To form the ridge, at least the semiconductor contact layer or the semiconductor contact layer and at least part of the cladding layer can be removed in the cover region. The ridge can thus be formed by a part of the semiconductor contact layer or the semiconductor contact layer and a part of the cladding layer remaining after the ridge formation, so that the top side in the contact region is formed by the material of the semiconductor contact layer, while the top side in the cover region is formed by the semiconductor material of the cladding layer. Due to the different electrical properties of the semiconductor contact layer and the cladding layer, the above-described different current injections in the contact region and in the cover region and thereby an effect defining the active region can be brought about.

According to a further embodiment, the ridge comprises a transparent electrically conductive contact layer. The transparent electrically conductive contact layer can be applied directly to the top side of the semiconductor layer sequence, i.e. in direct contact with the semiconductor material of the semiconductor layer sequence. In particular, the ridge can be formed by the contact layer in this case. For this purpose, the contact layer can be applied in the contact region after the semiconductor layer sequence has been grown. In particular, the contact layer can comprise a TCO as described above in connection with the cover layer. Furthermore, the ridge can be formed by the transparent electrically conductive contact layer and a part of the semiconductor layer sequence.

Furthermore, the transparent electrically conductive contact layer may comprise a first TCO, while the cover layer may comprise a different, second TCO. The first TCO may have a higher electrical conductivity and/or a lower electrical contact resistance to the semiconductor layer sequence than the second TCO. The different electrical properties of the materials of the cover layer and the contact layer may cause the above-described different current injections in the contact region and the cover region, and thereby an effect defining the active region. Alternatively or additionally, the second TCO may have a lower refractive index than the first TCO. Since the TCO of the contact layer is overmolded by the TCO of the cover layer, the waveguiding property in the semiconductor laser diode can be influenced so that an effect defining the active region can be produced.

According to a further embodiment, the cover layer comprises more than one TCO. In particular, the cover layer can have a first TCO in the contact region and a second TCO in the at least one cover region. The second TCO may be at least partially covered by the first TCO. For example, the second TCO may have a lower optical absorption than the first TCO. Furthermore, the first TCO may have a higher electrical conductivity and/or a higher electrical contact resistance to the semiconductor layer sequence than the second TCO.

According to a further embodiment, the at least one element defining the active region comprises or is formed by a damaged semiconductor structure in the at least one cover region. In particular, the damaged semiconductor structure may be formed on the top side of the semiconductor layer sequence. The damaged structure may be formed, for example, by an etching process. Particularly preferably, the etching process may be a dry etching process. In this case, the parameters of the etching process can be set such that the semiconductor material exposed to the etching medium is damaged by a plasma and/or ion bombardment. No or only very poor electrical contact to the cover layer is then formed at the damaged top side, so that no or essentially no current can be injected in this region, so that an effect defining the active region can be brought about by this. Particularly preferably, the damaged semiconductor structure can be combined with a ridge described above. In particular, the damaged semiconductor structure can be created as part of the ridge formation process.

According to a further embodiment, a metallic contact layer is arranged directly adjacent to the top side in the contact region on the top side of the semiconductor layer sequence. The metallic contact layer is covered in particular by the cover layer. Suitable materials for the metallic contact layer may be, for example, one or more metals selected from Pt, Pd, Rh and Ni. The metallic contact layer can enhance an electrical connection of the contact region to the cover layer, so that the metallic contact layer can also form a defining element.

Furthermore, the semiconductor laser diode can be free of dielectric materials affecting the active region on the top side. In other words, on the top side the semiconductor laser diode has no dielectric material, in particular no dielectric passivation common in the prior art, in those areas where such a dielectric material would have an influence on the at least one active region. Particularly preferably, the semiconductor laser diode may be free of dielectric materials on the top side. In other words, in this case no dielectric material at all, in particular no dielectric material in the form of a passivation, is present on the top side.

According to another embodiment, a plurality of contact regions are present on the top side. Further, a plurality of elements defining an active region may be present. In particular, a plurality of active regions may be present in the active layer during operation due to the plurality of defining elements, wherein a respective contact region is arranged above each of the active regions in the vertical direction. The plurality of defining elements is covered by the cover layer. The contact regions and/or the defining elements can each be formed identically or differently and have one or more of the features described above. The semiconductor laser diode can in particular be designed as a so-called laser bar. Particularly preferably, in this case, the semiconductor layer sequence and, in particular, the active layer can be designed to generate visible light, so that the semiconductor laser diode can be a multibeam emitter in the visible wavelength range.

Further, a plurality of cover regions may be present, wherein the contact regions are separated from each other by the cover regions. The cover layer may be arranged contiguously over the plurality of contact regions and the plurality of cover regions. Alternatively, the cover layer may be divided into sections separated from each other, each of the sections being associated with an active region and arranged in the manner described above on the respective associated contact region and the respective associated cover regions.

According to a further embodiment, the method of manufacturing the semiconductor laser diode may preferably comprise the following steps:
providing a substrate;
applying the semiconductor layer sequence by means of an epitaxial method;
covering the future contact region with a mask;
etching a ridge in the contact region and/or damaging the one or more cover regions laterally adjoining the contact region;
removing the mask;
applying, preferably over the entire surface, the transparent electrically conductive cover layer, which can particularly preferably form a p-contact for the semiconductor layer sequence;
applying one or more metallic contact elements to and/or on the cover layer.

The application of a further electrical contact, which can preferably then be an n-contact, and other necessary steps can take place at any points in the process flow. Alternatively or in addition to the production of the ridge and/or the production of the damaged semiconductor structure, a metallic or transparent electrically conductive contact layer can be applied in the contact region.

In the case of the semiconductor laser diode described here, the transparent electrically conductive cover layer is thus applied as described above after the completion of the semiconductor layer sequence, if necessary with a ridge and/or a damaged semiconductor structure, said transparent electrically conductive cover layer being in direct contact with the semiconductor material of the semiconductor layer sequence at least in the at least one cover region and preferably comprising at least one TCO or being made thereof. A dielectric passivation layer, on the other hand, which is commonly used in the prior art, can be omitted, in particular in the region of the top side of the semiconductor layer sequence in which the layers and elements deposited thereon have an influence on the properties of the active region. Since TCOs typically have a higher thermal conductivity than dielectrics, which are typically used for passivation, the thermal resistance at the top side can be reduced in the semiconductor laser diode described here, which can lead to improved output power, better high-temperature performance and reduced aging. Thus, the cover layer simultaneously forms a thermally conductive passivation and an electrical connection layer for contacting the semiconductor layer sequence. In addition, the manufacturing method can have a significantly simplified, self-aligning process control. As a result, manufacturing can be more cost-effective, faster and with better process stability than in the prior art.

### BRIEF DESCRIPTION OF THE DRAWINGS

Further advantages, advantageous embodiments and further developments will become apparent from the exemplary embodiments described below in connection with the figures.

In the figures:

FIGS. 1A to 1E show schematic representations of semiconductor layer sequences for semiconductor laser diodes and for method steps of methods of manufacturing semiconductor laser diodes according to several exemplary embodiments,

FIGS. 2A to 2C show a schematic representation of semiconductor laser diodes, in particular also in the context of methods of manufacturing the semiconductor laser diodes, according to further exemplary embodiments,

FIGS. 3 to 10 show schematic representations of semiconductor laser diodes according to further exemplary embodiments.

### DETAILED DESCRIPTION

In the exemplary embodiments and figures, equal or similar elements or elements of equal function may each be designated with the same reference signs. The elements shown and their proportions to one another are not to be regarded as true to scale; rather, individual elements, such as layers, components, structural elements and areas, may be shown exaggeratedly large for better representability and/or for better understanding.

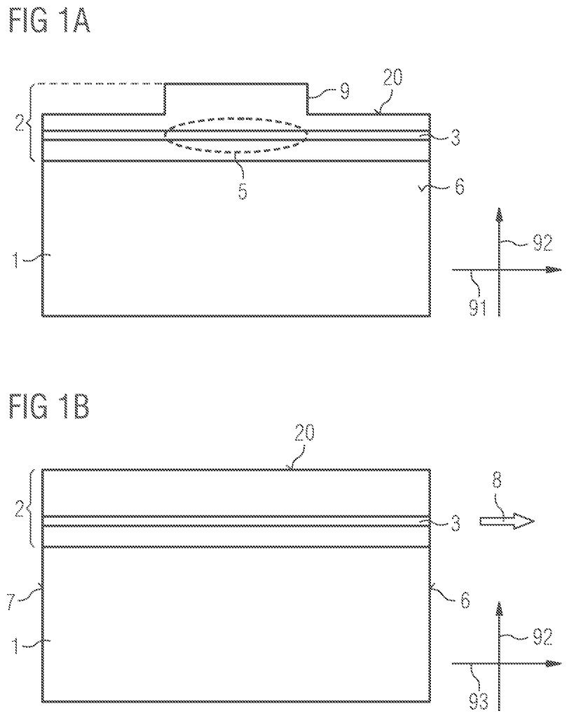

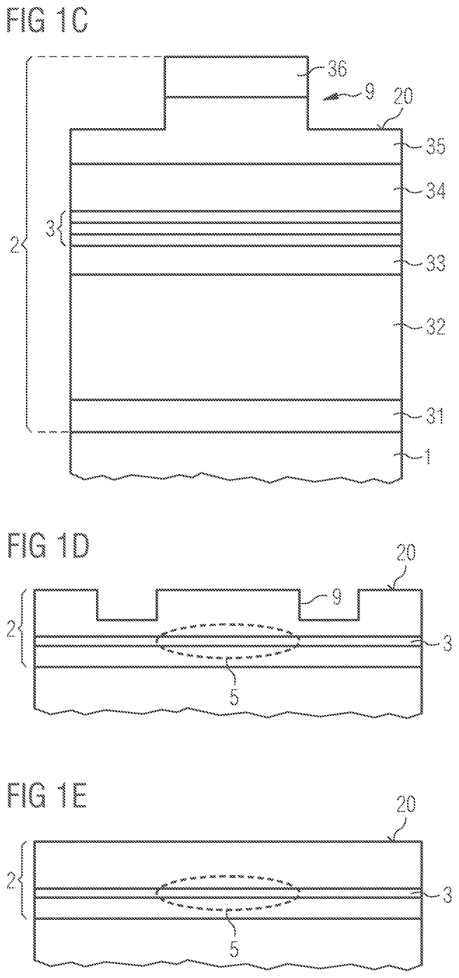

FIGS. 1A to 1E show exemplary embodiments of semiconductor layer sequences 2, each on a substrate 1, which are provided and used for the manufacture of the semiconductor laser diodes described below, where FIG. 1A shows a top view of the light outcoupling surface 6 of the later semiconductor laser diode and FIG. 1B shows a representation of a section through the semiconductor layer sequence 2 and the substrate 1 with a section plane perpendicular to the light outcoupling surface 6. FIG. 1C shows an exemplary embodiment of the structure of the semiconductor layer sequence 2. FIGS. 1D and 1E show modifications of the semiconductor layer sequence 2.

As shown in FIGS. 1A to 1C, a substrate 1 is provided which is, for example, a growth substrate for a semiconductor layer sequence 2 grown thereon by means of an epitaxial method. Alternatively, the substrate 1 may be a carrier substrate onto which a semiconductor layer sequence 2 grown on a growth substrate is transferred after growth. For example, the substrate 1 may be of GaN on which a semiconductor layer sequence 2 based on an InAlGaN compound semiconductor material is grown. Furthermore, other materials, in particular as described in the general part, may also be used for the substrate 1 and the semiconductor layer sequence 2. Alternatively, it is also possible that the completed semiconductor laser diode is free of a substrate. In this case, the semiconductor layer sequence 2 may be grown on a growth substrate which is subsequently removed. The semiconductor layer sequence 2 comprises an active layer 3 which is suitable for generating light 8, in particular laser light when the laser threshold is exceeded, during operation of the completed semiconductor laser diode and for emitting it via the light outcoupling surface 6.

As indicated in FIGS. 1A and 1B, here and in the following, the lateral direction 91 is referred to as a direction parallel to a main extension direction of the layers of the semiconductor layer sequence 2 when viewed from above the light outcoupling surface 6. The arrangement direction of the layers of the semiconductor layer sequence 2 on each other and of the semiconductor layer sequence 2 on the substrate 1 is referred to as the vertical direction here and in the following. The direction perpendicular to the lateral direction 91 and the vertical direction 92, which corresponds to the direction along which the light 8 is emitted when the completed semiconductor laser diode is in operation, is referred to here and in the following as the longitudinal direction 93.

In the top side 20 of the semiconductor layer sequence 2 facing away from the substrate 1, a ridge 9 is formed according to an exemplary embodiment by removing part of the semiconductor material from the side of the semiconductor layer sequence 2 facing away from the substrate 1. For this purpose, a suitable mask can be applied to the grown semiconductor layer sequence 2 in the region where the ridge is to be formed. Semiconductor material can be removed by an etching process. Subsequently, the mask can be removed again. The ridge 9 is formed by such a process in such a way that the ridge extends in the longitudinal direction 93 and is bounded on both sides in the lateral direction 91 by side surfaces, which can also be referred to as ridge side surfaces or ridge sides.

In addition to the active layer 3, the semiconductor layer sequence 2 may comprise further semiconductor layers, such as buffer layers, cladding layers, waveguide layers, barrier layers, current expansion layers and/or current limiting layers. As shown in FIG. 1C, the semiconductor layer sequence 2 on the substrate 1 may have, for example, a buffer layer 31, above it a first cladding layer 32 and above it a first waveguide layer 33, on which the active layer 3 is deposited. A second waveguide layer 34, a second cladding layer 35 and a semiconductor contact layer 36 may be provided above the active layer 3. In the shown exemplary embodiment, the ridge 9 is formed by the semiconductor contact layer 36 and a part of the second cladding layer 35, wherein for manufacturing the ridge 9 after growing the semiconductor layer sequence 2, a part of the semiconductor layer sequence 2 is removed from the top side 20. In particular, the removal may be performed by an etching process. Due to the refractive index jump at the side surfaces of the ridge 9 to an adjacent material as well as in case of a sufficient proximity to the active layer 3, a so-called index guidance of the light generated in the active layer 3 can be effected, which can significantly lead to the formation of an active region 5, which indicates the region in the semiconductor layer sequence 2 in which, during laser operation, the generated light is guided and amplified in the form of one or more laser modes. Thus, in this exemplary embodiment, the ridge 9 forms a so-called ridge waveguide structure and is an element defining the active region explained further below. It may also be possible for the ridge 9 to have a height less than or greater than the height shown, that is, less or more semiconductor material may be removed to form the ridge 9. For example, the ridge 9 may be formed by only the semiconductor contact layer 9 or a part thereof, or by the semiconductor contact layer 36 and the second cladding layer 35. By adjusting the height of the ridge 9, an adjustment of the index guidance can be achieved. As the height becomes smaller and/or the distance of the ridge 9 to the active layer 3 becomes bigger, the degree of the index guidance can be reduced. The mode guidance in the active region is then at least partly carried out by a so-called gain guidance.

If the semiconductor layer sequence 2 is based on an InAlGaN compound semiconductor material as described above, the buffer layer 31 may comprise or consist of undoped or n-doped GaN, the first cladding layer 32 may comprise or consist of n-doped AlGaN, the first waveguide layer 33 may comprise or consist of n-doped GaN, the second waveguide layer 34 may comprise or consist of p-doped GaN, the second cladding layer may comprise or consist of p-doped AlGaN, and the semiconductor contact layer 36 may comprise or consist of p-doped GaN. For example, Si may be used as the n-dopant, and Mg may be used as the p-dopant. The active layer 3 may be formed by a pn junction or, as indicated in FIG. 1C, by a quantum well structure having a plurality of layers formed, for example, by alternating layers with or of InGaN and GaN. For example, the substrate may comprise or be made of n-doped GaN. Alternatively, other layer and material combinations as described above in the general part are also possible.

Furthermore, reflective or partially reflective layers or layer sequence, which are not shown in the figures for clarity, can be applied to the light outcoupling surface 6 and the opposite rear surface 7, which form side surfaces of the semiconductor layer sequence 2 and the substrate 1, and which are provided and configured to form an optical resonator in the semiconductor layer sequence 2.

As can be seen in FIG. 1A, for example, the ridge 9 can be formed by completely removing semiconductor material laterally on both sides next to the ridge 9. Alternatively, a so-called “tripod” can be formed, as indicated in FIG. 1D, in which semiconductor material is removed laterally adjacent to the ridge 9 only along two grooves to form the ridge 9. Alternatively, the finished semiconductor laser diode can also be designed as a so-called broad stripe laser diode, in which the semiconductor layer sequence 2 is produced without a ridge or with a ridge of low height and is provided for the further method steps. Such a semiconductor layer sequence 2, in which the mode guiding can be based only or at least essentially on the principle of gain guiding, is shown in FIG. 1E.

The further method steps for manufacturing the semiconductor laser diode as well as exemplary embodiments of the semiconductor laser diode are explained in connection with the further figures. Purely by way of example, the exemplary embodiments are explained predominantly on the basis of a semiconductor layer sequence 2 with a ridge 9, as shown in FIGS. 1A to 1C. Alternatively, however, the following method steps and embodiments are also possible for the variants of the semiconductor layer sequence 2 shown in FIGS. 1D and 1E with a tripod structure or without a ridge. The detailed structure of the semiconductor layer sequence 2 shown in FIG. 1C is not to be understood restrictively and is not shown in the following figures for the sake of clarity.

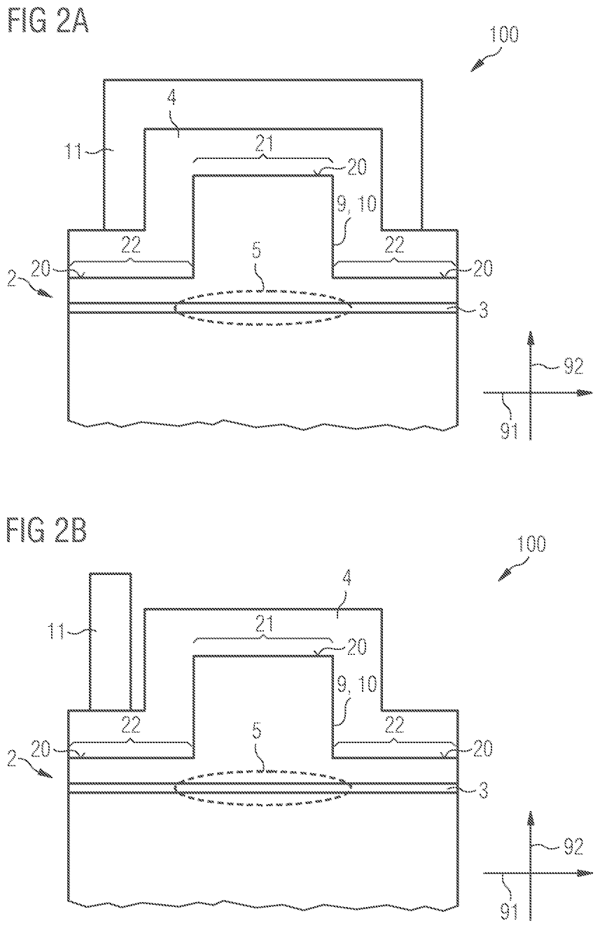

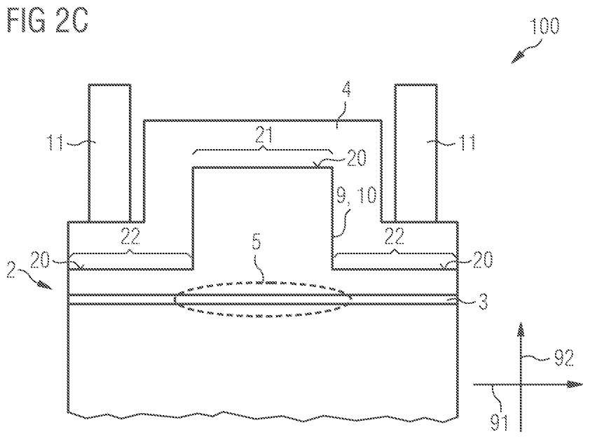

FIG. 2A shows a section of a semiconductor laser diode 100 with a semiconductor layer sequence 2, wherein the semiconductor layer sequence 2 is produced in a first method step as described above in connection with the production of the semiconductor laser diode 100 and is provided for the further method steps. In a further method step, a transparent electrically conductive cover layer 4 is applied to the top side 20. In particular, the top side 20 comprises a contact region 21 arranged in the vertical direction 92 above the at least one active region 5. Laterally offset from the contact region 21, the top side 20 comprises at least one cover region 22 directly adjacent to the contact region 21. In particular, laterally offset from the contact region 21 and directly adjacent to the contact region 21, there may be two cover regions 22 as shown. As can be seen in particular in FIG. 2A, the contact region 21 is arranged in the lateral direction 91 between the two cover regions 22, each of which is directly adjacent to the contact region 21 in the lateral direction 91. The following description, which mostly refers to exemplary embodiments with two cover regions, equally refers to embodiments of the semiconductor laser diode with one or more than two cover regions.

In the shown exemplary embodiment, the contact region 21 is formed by the top side of the ridge 9 and at least partially by the side surfaces of the ridge 9. Accordingly, the contact region 21 has a main extension direction along the longitudinal direction and, following the shape of the ridge 9, is preferably formed in the shape of a strip which can preferably extend from the radiation outcoupling surface to the rear surface. In the shown exemplary embodiment, the cover regions 22 are formed by the parts of the top side 20 not formed by the contact region 21, i.e. by the parts of the top side 20 arranged next to and adjacent to the ridge 9.

The transparent electrically conductive cover layer 4 is applied contiguously to the contact region 21 and the cover regions 22 on the top side. In the exemplary embodiment shown, the cover layer 4 thus covers the entire contact region 21 and the entire cover regions 22, so that the entire top side 20 is covered with the cover layer 4. In particular, in the exemplary embodiment shown, the cover layer 4 is in direct contact with the entire top side 20 of the semiconductor layer sequence 2, i.e., both in the contact region 21 and in the cover regions 22.

The transparent electrically conductive cover layer 4 comprises or is made of at least one TCO. In particular, the cover layer 4 may comprise or be made of one or more of the TCOs mentioned above in the general part, in particular selected from ITO, In₂O₃, SnO₂, Sn₂O₃, ZnO, IZO and GZO. The cover layer 4 is provided and configured to inject current from the top side into the semiconductor layer sequence 2 and thus into the active layer 3 during operation of the semiconductor laser diode 100, thus forming a transparent electrical contact. On the bottom surface of the semiconductor layer sequence 2 opposite the top side 20, an electrode layer can be applied as a further electrical contact (not shown).

For external electrical connection of the cover layer 4, at least one metallic contact element 11 is arranged on the side of the cover layer 4 facing away from the semiconductor layer sequence 2 or on the cover layer 4. The contact element 11 may be a bonding layer for wire bonding or for soldering on the semiconductor laser diode 100 and may, for example, have a single-layer or multilayer structure. For example, the contact element 11 may comprise or be made of aluminum and/or silver and/or gold. As shown, the contact element 11 is preferably arranged directly on the cover layer 4 and can be applied over a large area above the ridge 9, which can have a particular advantage when soldering on the semiconductor laser diode 100 with the contact element 11 and thus with the p-side facing downwards (“p-down”).

The exemplary embodiment shown in FIG. 2A as well as the further exemplary embodiments are designed in such a way that during operation more current is injected into the top side 20 of the semiconductor layer sequence 2 via the contact region 21 than via the cover regions 22. As explained in the general part, this may mean in particular that the current injection by means of the cover layer 4 is at least preferably or at least substantially or even exclusively performed via the contact region 21, while less current injection is performed during operation of the semiconductor laser diode 100 via the cover regions 22 than via the contact region 21 or substantially no current injection is performed or even no current injection is performed at all. In the exemplary embodiment of FIG. 2A, this is achieved by the fact that, due to the ridge 9, the contact region 21 is completely formed by the semiconductor contact layer described in connection with FIG. 1C at the ridge top side and is at least partially formed by the semiconductor contact layer described in connection with FIG. 1C at the ridge side surfaces, while the cover regions 22 are formed by the second cladding layer or the second waveguide layer, each of which has a significantly lower doping than the semiconductor contact layer. Furthermore, the semiconductor contact layer may have a lower aluminum content or even no aluminum compared to the underlying layers. As a result, the contact region 21 has a lower electrical contact resistance to the cover layer 4 than the cover regions 22, which can promote the desired higher current injection in the contact region 21.

Thus, the current injection from the top side 20 can be influenced by the ridge 9 in the described manner. Furthermore, as described in connection with FIGS. 1A to 1C, the ridge 9 can be formed as a ridge waveguide structure and thereby cause index guiding of the light generated in the active layer 3 during operation. Since both the selective current injection via the contact region 21 and the index guiding caused by the ridge waveguide structure contribute to the formation of the active region 5, and since the active region 5 can be modified by changing the ridge 9, the ridge 9 forms an element defining the active region 10, as mentioned above, which is also referred to as a defining element for short, as described in the general part. As shown and previously described, the defining element 10 is covered by the cover layer 4, which serves, on the one hand, as a transparent contact for current supply. In particular, since the cover layer 4 also directly covers the ridge side surfaces, the cover layer 4 also has an effect on the wave guiding of the ridge waveguide structure due to the refractive index jump at the corresponding boundary surfaces, on the other hand. Furthermore, the cover layer 4 shields the optical modes in the semiconductor material from the metal of the contact element 11. As a result, the semiconductor laser diode 100 shown does not require a passivation layer on the ridge, which is commonly used in the prior art, so that the semiconductor laser diode 100 according to the exemplary embodiment shown can be free of any dielectric material on the top side 20. Furthermore, as in the shown exemplary embodiment, it may be possible that no separate metallic contact connection layer is present on the ridge top side.

As an alternative to a metallic contact element 11 covering the entire contact region 21 over a large area, the contact element can also be arranged as one contact element 11 or also as a plurality of contact elements 11 only in one or more specific areas on the cover layer 4 which is/are required for electrical connection by soldering or wire bonding. As shown in FIGS. 2B and 2C, it may be possible, for example, for a contact element 11 to be arranged only laterally adjacent to the contact region 21 and thus, in the exemplary embodiment shown, adjacent to the ridge 9 on one side or, in the form of two metallic contact elements 11, on both sides. The lateral arrangement can serve as a mechanical relief for the ridge 9, in particular in the “tripod” type structure shown in FIG. 2C, for example in a “p-down” solder assembly with the contact elements 11 on a carrier. Furthermore, the cover layer 4 in the shown exemplary embodiments of FIGS. 2B and 2C may be thinner compared to the exemplary embodiment of FIG. 2A, since no contact absorption is expected from the metallic contact element 11.

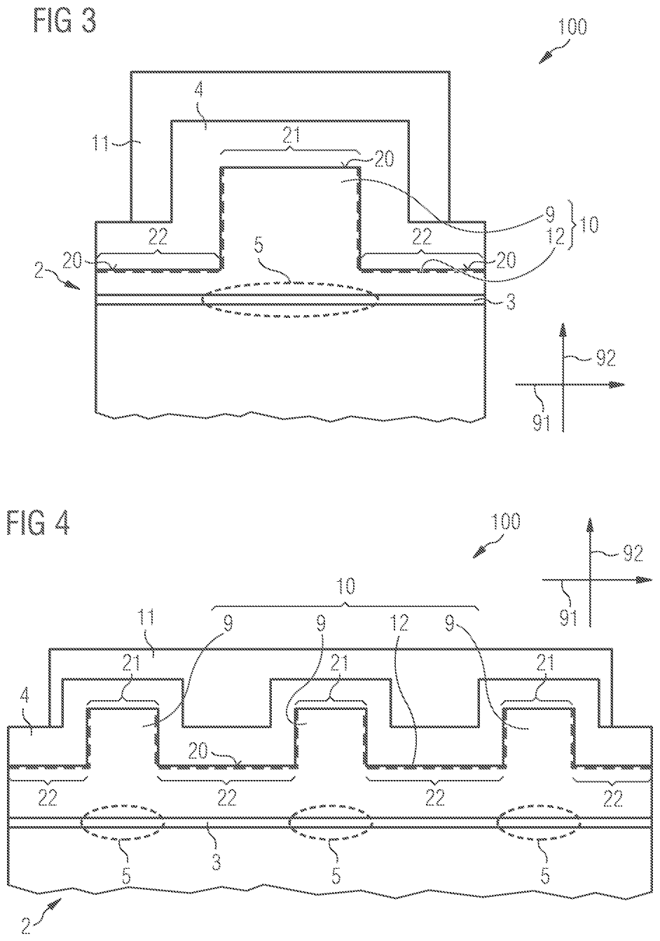

FIG. 3 shows an exemplary embodiment of a semiconductor laser diode 100 in which, compared to the previous exemplary embodiments, a damaged semiconductor structure 12 is produced in the cover regions 22 as an additional defining element 10 for forming the active region 5. Moreover, in this exemplary embodiment, the cover regions 22 also include the ridge side surfaces, while the contact region 21 is formed by the ridge top side. The damaged semiconductor structure 12 is formed on the top side 20 of the semiconductor layer sequence 2 exposed after the ridge formation, except for the ridge top side. In particular, the damaged semiconductor structure 12 may be formed as part of the ridge formation process, especially as a final step of the ridge formation process. For example, the damaged structure 12 may be produced by an etching process and/or sputtering, which may particularly preferably be a dry etching process. The parameters of the etching process are adjusted such that the semiconductor material exposed to the etching medium is damaged by a plasma and/or ion bombardment. No or only very poor electrical contact to the cover layer 4 is then formed at the damaged top side with the damaged semiconductor structure 12, so that preferably no or essentially no current can be injected in this area. This effect can be further enhanced, as described in connection with the previous exemplary embodiments, by removing the highly doped semiconductor contact layer at the side of the ridge 9 in the cover region 22. In the following exemplary embodiments, a damaged semiconductor structure 12 is always shown purely as an example. Alternatively, the following exemplary embodiments can also be designed without a damaged semiconductor structure.

While single emitters are shown in the previous exemplary embodiments, the semiconductor laser diode 100 may also be designed as a so-called laser bar or multibeam emitter. As shown in FIG. 4, a plurality of contact regions 21 may be provided on the top side 20. Accordingly, there is also a plurality of elements 10 defining an active region which serve to form laterally juxtaposed active regions 5 each vertically below the contact regions 21. As in the previous exemplary embodiments, the plurality of defining elements 10 are covered by the cover layer 4 and, purely by way of example, have ridges 9 and a damaged semiconductor structure 12. Purely by way of example, the semiconductor laser diode 100 of the exemplary embodiment of FIG. 4 is designed analogously to the exemplary embodiment of FIG. 3. The contact regions 21 and/or the defining elements 10 may each be generally the same or different. Further, a plurality of cover regions 22 are provided, wherein the contact regions 21 are separated from each other by the cover regions 22. As shown, the cover layer 4 may be arranged contiguously over the plurality of contact regions 21 and the plurality of cover regions 22. This allows simultaneous control of all active regions 5. Alternatively, the cover layer 4 may be divided into sections separated from each other, each of the sections being associated with an active region 5 and arranged in the manner described above on the respective associated contact region 21 and partially on the respective associated cover regions 22, so that the active regions 5 can be actuated independently of each other. In this case, each active region 5 is assigned its own metallic contact element. Particularly preferably, the semiconductor layer sequence 2 and, in particular, the active layer 3 can be designed to generate visible light, so that the semiconductor laser diode 100 can be a multibeam emitter in the visible wavelength range. The features described in connection with the previous exemplary embodiments as well as in connection with the following exemplary embodiments can in each case also apply to the semiconductor laser diode 100 of FIG. 4.

FIG. 5 shows a further exemplary embodiment for a semiconductor laser diode 100 in which, compared to the previous exemplary embodiments, a metallic contact layer 13 is arranged in the contact region 21 on the semiconductor layer sequence 2. In particular, the metallic contact layer 13 is arranged directly adjacent to the top side 20 in the contact region 21 on the top side 20 of the semiconductor layer sequence 2 and is covered by the transparent electrically conductive cover layer 4. For example, one or more metals selected from Pt, Pd, Rh and Ni may be used as materials for the metallic contact layer 13. The metallic contact layer 13 can enhance the electrical connection of the top side 20 in the contact region 21 to the cover layer 4 by reducing the electrical contact resistance, so that the current injection from the cover layer 4 into the semiconductor layer sequence 2 in the contact region 21 can be strengthened, which can affect the formation of the active region below the contact region 21. Therefore, the metallic contact layer 13 may also form a defining element 10. Since the semiconductor laser diode 100 in this configuration, as in the other exemplary embodiments, may be free of dielectric passivation, i.e., free of dielectric materials on the top side 20, a better, i.e., lower thermal resistance on the top side may be achieved compared to the prior art.

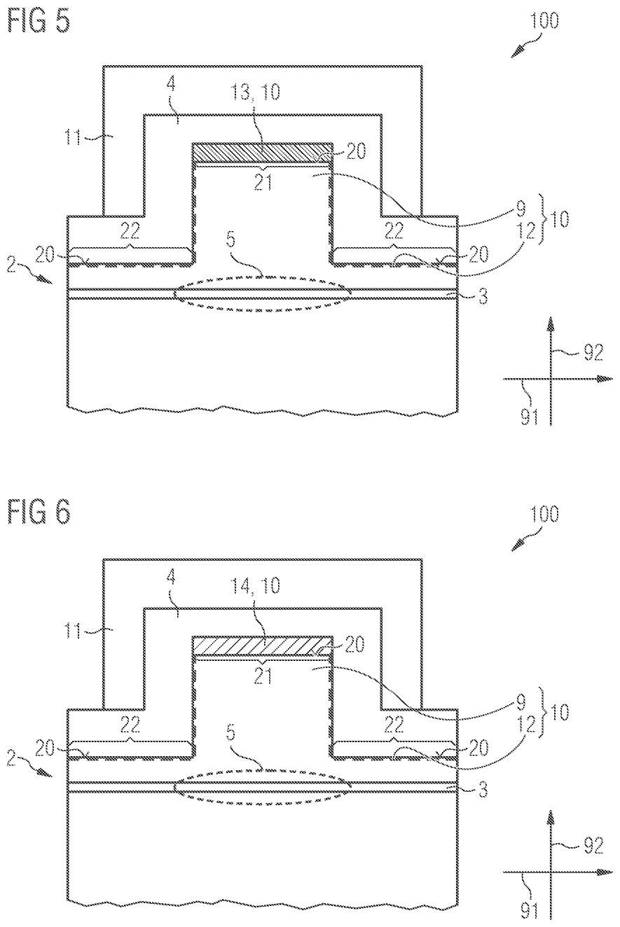

FIG. 6 shows an exemplary embodiment of a semiconductor laser diode 100 which, compared to the previous exemplary embodiment, has a transparent electrically conductive contact layer 14 directly on the contact region 21 instead of the metallic contact layer 13. The transparent electrically conductive contact layer 14 can thus form the ridge 9 with the underlying semiconductor material of the semiconductor layer sequence 2 in the contact region 21, so that the ridge 9 can be formed by semiconductor material of the semiconductor layer sequence 2 and by the material of the transparent electrically conductive contact layer 14. In particular, the transparent electrically conductive contact layer 14 may comprise a TCO as described above in connection with the cover layer 4. The transparent electrically conductive contact layer 14 preferably comprises a first TCO, while the cover layer 4 comprises a second TCO different therefrom. The first TCO may preferably have a higher electrical conductivity and/or a lower electrical contact resistance to the semiconductor layer sequence 2 than the second TCO. For example, the first TCO may comprise or be ITO or ZnO, while the second TCO may be a different TCO or have a different stoichiometry. As in the previous exemplary embodiment, the different electrical properties of the materials of the cover layer 4 and the transparent electrically conductive contact layer 14 can promote the different current injections in the contact region 21 and the cover region 22 described above, which can cause an effect defining the active region.

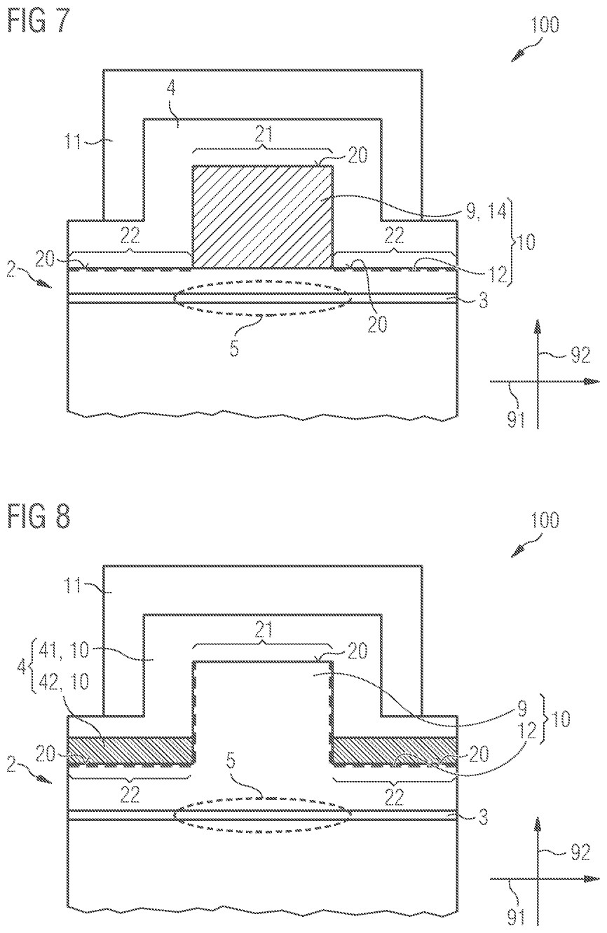

As shown in FIG. 7, the ridge 9 can also be formed by the transparent electrically conductive contact layer 14. Thus, it may be possible to achieve a very cost-effective production of the ridge 9 and, in particular, of a ridge waveguide structure. In particular, a first TCO can be deposited on the top side of the finished semiconductor layer sequence 2 in the contact region 21 and structured to form a strip, said TCO forming the transparent electrically conductive contact layer 14. At the same time, the area next to the strip, i.e. the cover regions 22, can be prepared by suitable measures, such as damage and/or sputtering and/or oxidation, in such a way that the formation of the damaged semiconductor structure 12 makes an electrical contact resistance to materials applied later, i.e. in particular the material of the cover layer 4, high. A second TCO having a lower refractive index than the first TCO is deposited on and adjacent to the first TCO of the transparent electrically conductive contact layer 14 to form the cover layer 4. This in turn creates a lateral refractive index jump for the optical wave generated in the active layer 3 during operation, which creates the lateral wave guidance described above, i.e., the index guidance. At the same time, it can be achieved that current is injected into the top side 20 of the semiconductor layer sequence 2 only or at least substantially only in the region with higher refractive index, i.e. in the contact region 21, so that a so-called self-aligned ridge laser is formed. As in the previous exemplary embodiment, the contact layer 14 and the cover layer 4 may comprise or consist of different TCOs, i.e., different materials such as zinc oxide and tin oxide, and/or have different material compositions and/or stoichiometries. A particular advantage of this exemplary embodiment may be that essentially no semiconductor material needs to be etched, and thus the lateral refractive index jump does not need to be adjusted by an exact etch depth, which is technically more difficult to achieve. Rather, only a coating with the material of the transparent electrically conductive contact layer 14 is necessary, which can be selected to have the correct refractive index and can be applied with the correct thickness.

Further, as shown in FIG. 8, the cover layer 4 may comprise more than one TCO. In particular, the cover layer 4 can have or be made of different layers with different TCOs. This option can be combined with the other exemplary embodiments described herein. In particular, the cover layer 4 may have a first layer 41 with a first TCO at least in the contact region 21 and a second layer 42 with a second TCO different from the first TCO in the cover regions 22. The second TCO may be at least partially covered by the first TCO. Thus, the first layer 41 may cover the second layer 42 in the cover regions as shown. In particular, as shown, the second layer 42 may be arranged only in the cover regions 22, so that the second layer 42 is arranged neither above nor below the first layer 41 in the contact region 21. Thus, the transparent contact formed by the cover layer 4 may be formed of multiple layers, preferably with the second layer 42 not extending over the contact region 21.

For example, a second TCO with particularly low absorption can be used in the cover regions 22, i.e. in the area next to the contact region 21, which in the embodiment shown also means next to the ridge 9, but which has, for example, a poorer electrical conductivity than the first TCO. This is covered by the first TCO with a high electrical conductivity, which then also forms the electrical connection to the semiconductor material in the contact region 21. The first TCO may, for example, have a higher optical absorption than the second TCO. The first and second layers 41, 42 of the cover layer 4 can thus additionally form a defining element 10.

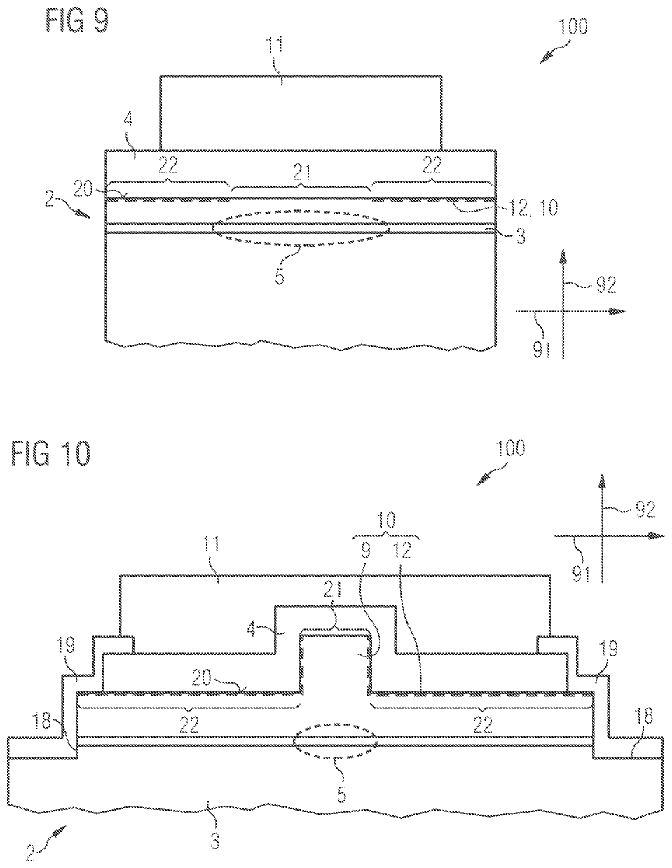

The exemplary embodiments of FIGS. 2A to 8 each include a ridge 9, which may provide index guidance depending on how it is formed. Alternatively, the semiconductor laser diode 100 may have the features described above for defining the active region 5 except for a ridge 9 and thus be based on the principle of gain guiding. In FIG. 9, purely by way of example, a semiconductor laser diode 100 is shown which, except for the ridge, is designed like the exemplary embodiment of FIG. 3 and is designed as a gain-guided laser in which the top side 20 is only not damaged in a contact window which forms the contact region 21, for example by plasma or sputtering to form the damaged semiconductor structure 12 in the cover region 22. As a result, no step or only a very small step is formed in the top side 20, so that substantially no ridge or a ridge having only a very small height is formed. In particular, the top side 20 in the cover region 22 as in the contact region 21 may be formed by the semiconductor contact layer, which may typically have a thickness in the range of 30 nm to 200 nm and which is also at most only partially removed in the cover region 22. If a ridge is thus present, it has a smaller height than the thickness of the semiconductor contact layer. Due to the damaged semiconductor structure 12, it can be achieved as described above that an electrical contact between the semiconductor layer sequence 2 and the cover layer 4 is effectively only present in the contact region 21.

As an alternative to the previous exemplary embodiments, in which the cover layer 4 always covers the entire top side 20 of the semiconductor layer sequence 2 in each case, the cover layer 4 in the exemplary embodiments shown can also cover only part of the top side 20 of the semiconductor layer sequence 2. The part of the top side 20 not covered by the cover layer 4 in this case is then selected in each case in such a way that it has no influence on the formation of the active region 5 and thus on the optical properties of the semiconductor laser diode 100, whether the cover layer 4 is present in this part or not. In particular, the cover layer 4 always extends laterally so far over the top side 20 of the semiconductor layer sequence 2 and thus over the contact region 21 and at least a part of the cover regions 22 that the region or regions not covered by the cover layer 4 have no influence on the active region 5. Therefore, the previously shown exemplary embodiments may also form sections of semiconductor laser diodes 100 in which further elements may be present in the lateral direction 91 further away from the active region 5. FIG. 10 shows an exemplary embodiment for a semiconductor laser diode 100 which corresponds to the exemplary embodiment of FIG. 3 in terms of its design around the active region 5 purely by way of example. In the lateral direction 91 further away from the active region 5, mesa trenches 18 are present in the semiconductor layer sequence 2 on both sides adjacent to the active region in this exemplary embodiment, which trenches extend through the active layer 3 and which may be passivated with a dielectric material 19. However, the dielectric material 19 has no influence on the laser modes and thus on the active region 5. Thus, the semiconductor layer sequence 2 around the contact region 21 is covered only with the cover layer 4 and the electrical contact element 11 to ensure good heat transport. As shown, the cover layer 4 and the semiconductor layer sequence 2 may be completely or partially covered with the dielectric material 19, for example, in regions remote from the active region 5, which may be uncovered by the electrical contact element 11. As a result, the semiconductor laser diode 100 can be more stable against chemical influences, and leakage currents, for example at the mesa edges, can be avoided.

The exemplary embodiments and features shown in the figures are not limited to the combinations shown in the figures in each case. Rather, the shown exemplary embodiments as well as individual features can be combined with each other, even if not all possible combinations are explicitly described. Furthermore, the exemplary embodiments described in the figures may alternatively or additionally have further features as described in the general part.

The invention is not limited to the exemplary embodiments by the description based on the same. Rather, the invention encompasses any new feature as well as any combination of features, which in particular includes any combination of features in the patent claims, even if this feature or combination itself is not explicitly stated in the patent claims or embodiments.

1. A semiconductor laser diode, comprising
a semiconductor layer sequence grown in a vertical direction and having an active layer that is configured and provided to generate light during operation in at least one active region extending in a longitudinal direction, and
a transparent electrically conductive cover layer on the semiconductor layer sequence, wherein
the semiconductor layer sequence terminates in a vertical direction with a top side, and the top side comprises a contact region arranged in the vertical direction above the active region and at least one cover region directly adjoining the contact region in a lateral direction perpendicular to the vertical and longitudinal directions,
the cover layer is applied contiguously on the top side to the contact region and the at least one cover region,
the cover layer is applied directly to the top side of the semiconductor layer sequence at least in the at least one cover region,
at least one element defining the at least one active region is present which is covered by the cover layer, and
the semiconductor laser diode is free of dielectric materials on the top side.

2. The semiconductor laser diode according to claim 1, wherein the cover layer comprises a transparent conductive oxide.

3. The semiconductor laser diode according to claim 1, wherein a metallic contact element is arranged on the side of the cover layer facing away from the semiconductor layer sequence.

4. The semiconductor laser diode according to claim 3, wherein the contact element is a bonding layer for wire bonding or soldering on the semiconductor laser diode.

5. The semiconductor laser diode according to claim 1, wherein the at least one element defining the active region comprises a ridge formed in the contact region of the top side.

6. The semiconductor laser diode according to claim 5, wherein the ridge is formed by a part of the semiconductor layer sequence.

7. The semiconductor laser diode according to claim 5, wherein the ridge forms a ridge waveguide structure for index guidance of the light generated in the active region.

8. The semiconductor laser diode according to claim 5, wherein the ridge has a height which is so small that no index guidance of the light generated in the active region is caused by the ridge.

9. The semiconductor laser diode according to claim 6, wherein the ridge comprises a transparent electrically conductive contact layer.

10. The semiconductor laser diode according to claim 5, wherein the ridge is formed by a transparent electrically conductive contact layer formed by a transparent conductive oxide.

11. The semiconductor laser diode according to claim 1, wherein the at least one element defining the active region comprises a damaged semiconductor structure in the at least one cover region.

12. The semiconductor laser diode according to claim 11, wherein the damaged semiconductor structure is formed at the top side of the semiconductor layer sequence.

13. The semiconductor laser diode according to claim 1, wherein a metallic contact layer or a transparent electrically conductive contact layer, which is covered by the cover layer, is arranged directly adjacent to the top side in the contact region on the top side of the semiconductor layer sequence.

14. The semiconductor laser diode according to claim 1, wherein the cover layer comprises a first layer comprising a first transparent conductive oxide at least in the contact region and a second layer comprising a second transparent conductive oxide different from the first transparent conductive oxide in the at least one cover region, and the second transparent conductive oxide is at least partially covered by the first transparent conductive oxide such that the first layer covers the second layer in the at least one cover region.

15. The semiconductor laser diode according to claim 14, wherein the second layer is arranged only in the at least one cover region.

16. (canceled)

17. The semiconductor laser diode according to claim 1, wherein
a plurality of contact regions are present on the top side,
a plurality of active regions are present in the active layer during operation, and a respective contact region is arranged above each of the active regions in the vertical direction,
the contact regions are separated from each other by cover regions of a plurality of cover regions, and
a plurality of elements defining the active regions are present which are covered by the cover layer.

18. The semiconductor laser diode according to claim 17, wherein the cover layer is arranged contiguously over the plurality of contact regions and the plurality of cover regions.

19. The semiconductor laser diode according to claim 17, wherein the cover layer is divided into sections separated from each other and each of said sections is associated with an active region.

20. A method of manufacturing a semiconductor laser diode according to claim 1, in which
the semiconductor layer sequence having the active layer and the top side with the contact region and the at least one cover region is provided,
the at least one element defining the active region is formed, and
the cover layer is applied contiguously to the contact region and the at least one cover region.

21. A semiconductor laser diode, comprising:
a semiconductor layer sequence grown in a vertical direction and having an active layer that is configured and provided to generate light during operation in at least one active region extending in a longitudinal direction; and
a transparent electrically conductive cover layer on the semiconductor layer sequence, wherein
the semiconductor layer sequence terminates in a vertical direction with a top side, and the top side comprises a contact region arranged in the vertical direction above the active region and at least one cover region directly adjoining the contact region in a lateral direction perpendicular to the vertical and longitudinal directions,
the cover layer is applied contiguously on the top side to the contact region and the at least one cover region,
the cover layer is applied directly to the top side of the semiconductor layer sequence at least in the at least one cover region,
at least one element defining the at least one active region is present which is covered by the cover layer, and
the at least one element defining the active region comprises a ridge formed in the contact region of the top side, wherein the ridge is formed by a transparent electrically conductive contact layer formed by a transparent conductive oxide.
